(19) United States
(12) Patent Application Publication
(10) Pub. No.: US 2003/0006488 A1
(43) Pub. Date: Jan. 9, 2003

(54) Lead frame and manufacturing method of the same

(76) Inventors: Shinichi Wakabayashi, Nagano (JP); Shoji Koizumi, Nagano (JP); Shoichi Koyama, Nagano (JP)

Correspondence Address: ARMSTRONG,WESTERMAN & HATTORI, LLP, 1725 K STREET, NW., SUITE 1000, WASHINGTON, DC, 20006, US

(21) Appl. No.: 10/183,953

(22) Filed: Jun. 28, 2002

(30) Foreign Application Priority Data
Jul. 3, 2001 (JP) 2001-201951

(51) Int. Cl. H01L 21/44

(52) U.S. Cl. 257/666; 438/123

(57) ABSTRACT

Disclosed is a lead frame, including an inner lead, an outer lead connected to the inner lead, and an insulating film covered on the inner lead, the insulating film having an opening formed on a predetermined area of the inner lead electrically connected to a semiconductor chip.

### BACKGROUND OF THE INVENTION

1. Field of the Invention

The present invention relates to a lead frame for mounting of a semiconductor chip, and a manufacturing method of the same.

2. Description of the Related Art

In recent years, an LSI technology as a key technology for realizing multimedia equipment has steadily been developed toward a higher speed and a larger capacity for data transmission. In connection with this, progress has been made toward a higher density for a mounting technology as an interface between the LSI and an electronic device.

As a result, arraying pitches of terminals (pins) of an incorporated electronic component have been narrowed, and the number of terminals has also been increased to form a multiple pin structure. Recently, for example, a lead frame has been developed, in which the number of terminals is 256, and a lead pitch is 130 m or less. FIG. 1 is a schematic plan view showing a conventional lead frame. As shown in FIG. 1, a conventional lead frame 100 has a frame structure, which is constructed by a pair of outer frames 102 extended in parallel with each other, and a pair of inner frames 104 connected with the to the outer frames 102. In a center of the lead frame, a square die pad 106 is disposed for mounting a semiconductor chip.

This die pad 106 is supported by a support-bar 107. In addition, a lead 108 constituted of pluralities of inner and outer leads 108a, 108b is extended from the inner and outer frames 104 and 102 toward the die pad 106. Especially, in the lead frame of narrow pitches, electric short-circuiting easily occurs because of contact between tips of the inner leads 108. Accordingly, in order to prevent electric short-circuiting between the inner leads 108a, as shown in FIG.1, a fixing tape 110 made of a polyimide film or the like is stuck over a plurality of inner leads 108a in a pitch direction, and the plurality of inner leads 108a are fixed and supported, thereby preventing contact between the tips thereof.

However, in the above method of sticking the fixing tape over the inner leads 108a, in the case that lead pitches are further narrowed, there is a possibility that the tips thereof may contact. Thus, requests have been made for a lead frame capable of preventing electric short-circuiting caused by contact between inner leads, even if lead pitches are further narrowed, and a manufacturing method of the same.

### SUMMARY OF THE INVENTION

It is an object of the present invention to provide a lead frame capable of preventing electric short-circuiting even in the case of a lead having very narrow pitches, and a manufacturing method of the same.

A lead frame of the present invention includes an inner lead, an outer lead connected to the inner lead, and an insulating film covered on the inner lead, the insulating film having an opening formed on a predetermined area of the inner lead electrically connected to a semiconductor chip.

According to the present invention, all the surfaces including a front, rear and side surfaces of a predetermined area other than a portion electrically connected through a wire to the semiconductor chip of the inner lead of the lead frame are covered with the insulating film. For example, an organic insulation film is used as the insulated film. That is, since portions other than a bonding area of the inner lead are covered with the insulating film, there is no possibility of electric short-circuiting even if the inner leads of narrow pitches are brought into contact with each other.

Thus, pitches of the inner leads of the lead frame can be narrowed as requested in designing, and high-density mounting can be dealt with. Moreover, in a semiconductor device with semiconductor chip highly densely mounted on the lead frame of narrow pitches, manufacturing yield can be raised.

In carrying out our invention in one preferring mode, an area of the inner lead including at least the opening of the insulating film may be subjected to coining treatment after the formation of the opening.

When the inner leads of narrow pitches are covered with the insulating film, and the opening is formed for electric connection, the case where an area of the opening becomes smaller than an area requested in designing is assumed. According to the one preferring mode, since the area including the opening of the tip part of the inner lead is subjected to coining treatment, and an alloy substrate of this area is accordingly extended, the area of the opening can be increased following such extension. Thus, since the opening having a sufficient area can also be secured in the inner leads of narrow pitches, reliability of electric connection with the semiconductor chip through the wire can be improved. Moreover, even if the alloy substrate of the inner leads is extended in a pitch direction because of the coining treatment, facilitating contact between the inner leads, there is no possibility of electric short-circuiting as the inner leads are covered with the insulating film.

Further, the present invention relates to a method for manufacturing a lead frame, including the steps of preparing a lead frame including an inner lead having a metal-plated layer, coating an insulating film on the inner lead and forming an opening by pattering a required portion of the insulating film.

According to the present invention, first, a predetermined area of the inner lead of the lead frame is covered with the insulating film. Then, the opening is formed on the insulating film to secure an area for electric connection with the semiconductor chip.

In one preferring mode, a photosensitive organic insulating film may be used as an insulating film, and the opening may be formed by exposing and developing the insulating film. Also, the opening may be formed by laser trimming. By using such a manufacturing method, the above-described lead frame can be easily manufactured.

### BRIEF DESCRIPTION OF THE DRAWINGS

FIG. 1 is a plan view showing a lead frame according to prior art.

FIG. 2A is a plan view showing a lead frame according to an embodiment of the present invention.

FIG. 2B is an enlarged partial plan view showing an expanded tip of an inner lead shown in FIG. 2A.

FIG. 2C is a partial sectional view taken with line I-I in FIG. 2B.

FIGS. 3A to 3C are partial plan and sectional views showing a first manufacturing method of the lead frame according to the embodiment of the present invention.

FIG. 4A is a partial plan view showing an example of an exposure mask in the first manufacturing method of the lead frame according to the embodiment of the present invention.

FIG. 4B is a partial plan view showing an example of an inner lead of a lead frame manufactured by the first manufacturing method.

FIG. 5 is a partial plan view showing a modification of the first manufacturing method of the lead frame of the embodiment of the present invention.

FIGS. 6A and 6B are partial plan and sectional views showing a second manufacturing method of the lead frame according to the embodiment of the present invention.

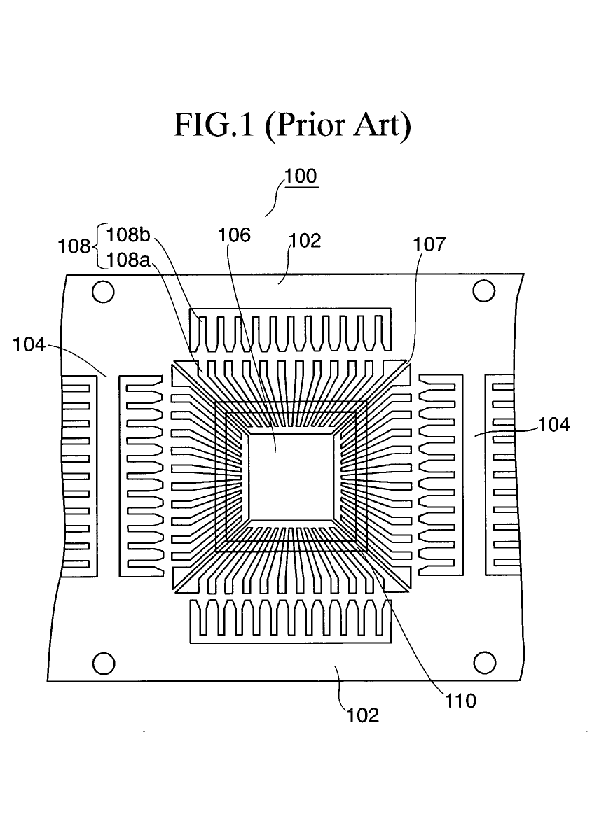

### DESCRIPTION OF THE PREFERRED EMBODIMENTS

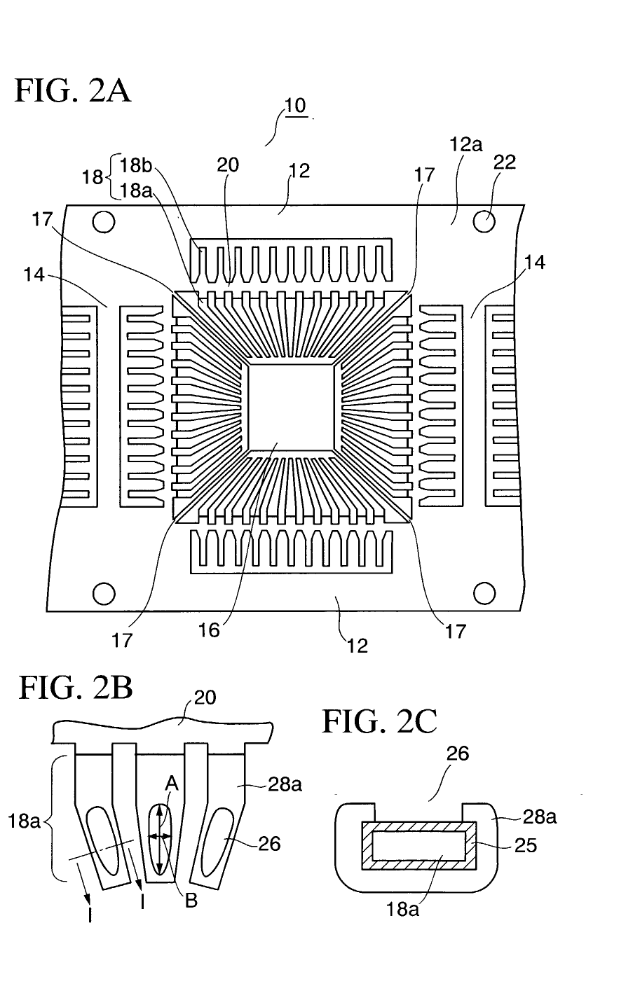

The preferred embodiments of the present invention will be described with reference to the accompanying drawings. FIG. 2A is a partial plan view showing a lead frame according to an embodiment of the present invention, FIG. 2B is an enlarged partial plan view showing an expanded tip of an inner lead shown in FIG. 2A, and FIG. 2C is a partial sectional view taken with line I-I in FIG. 2B. As shown in FIG. 2A, a lead frame 10 of the embodiment of the present invention is manufactured by etching or stamping a Fe—Ni alloy sheet or a Cu alloy sheet or the like. The lead frame 10 has a frame structure composed of a pair of outer frames 12 extended in parallel with each other, and a pair of inner frames 14 connected to the pair of outer frames 12 and arranged orthogonally to the outer frames. A guide hole 22 is formed in each outer frame 12. In a center of the lead frame, a quadrilateral die pad 16 is disposed so as to arrange a semiconductor chip. This die pad 16 is supported by four support-bars 17 extended from large width parts 12a of corners of the lead frame.

A plurality of leads 18 are extended from the inner and outer frames 14 and 12 toward the die pad 16. The leads 18 are extended in parallel with each other, and connected by dam-bar 20. Each lead 18 includes an inner lead 18a electrically connected to the semiconductor chip through a wire, and an outer lead 18b electrically connected to a wiring of a wiring substrate.

A pitch of the inner leads 18a is set to about 200 μm or less. Preferably, for example, a width of the inner lead 18a is set to about 80 μm, and a space width between the inner leads 18a is set to about 40 μm. As shown in FIGS. 2B and 2C, a metal plating layer 25 such as gold (Au) plating layer or silver (Ag) plating layer or the like is formed on the inner lead 18a, and this metal plating layer 25 is covered with a cured resist film 28a as an example of an organic insulating film. Further, in order to expose an area of the inner lead 18a electrically connected to a semiconductor chip through a wire, the cured resist film 28a of this area of the inner lead 18a is removed, thereby, an opening 26 is prepared.

For the cured resist film 28a, a modified epoxy (glycidyl ether) resin of a UV curing type (negative type), an acrylic resin, a thermoplastic resin or the like can be used.

In the embodiment of the present invention, the inner lead 18a of the lead frame 10 has a width of about 80 μm.

In this case, the opening 26 shown in FIG. 2B has a length A of about 500 μm, and a width B of about 60 μm. The width, pitch of the inner lead 18a, and the dimension of the opening 26 are properly adjusted in accordance with a mounting trend. Preferably, however, a width B is set to 60 μm or more so as to enable stable wire bonding. The lead frame 10 of the present embodiment is constructed in the foregoing manner. Though not specified, first, the semiconductor chip is mounted (die-bonded) on the die pad 16, and an electrode for introducing the lead of the semiconductor chip is connected through a wire to the opening 26 of a corresponding inner lead 18a. Then, resin molding is executed by covering the semiconductor chip, a portion of inner lead 18 connected with the wire or the like, and unnecessary lead frame portions are cut and removed, thereby the semiconductor device which the semiconductor chip is mounted on is manufactured.

According to the lead frame 10 of the embodiment, the inner lead 18a is covered with the cured resist 28a, and the opening 26 having the inner lead 18a exposed is formed in a and predetermined area for electric connection with the semiconductor chip, thus securing an area for electric connection. For example, even in the case of an inner lead having a very narrow pitch of 200 Mm or less, even if the inner leads 18a are brought into contact with each other in the foregoing resin molding step or the step of cutting and removing unnecessary lead frame portions, since portions other than the opening 26 for performing electric connection are covered with the cured resist film 28a, no electric short-circuiting occurs.

Accordingly, a pitch of the inner leads 18a of the lead frame 10 can be narrowed as requested in designing (for example, 200 μm or less), and high-density mounting can be dealt with. Moreover, since electric short-circuiting can be prevented between the inner leads 18a, it is possible to increase yield of the semiconductor device with the semiconductor chip mounted on the lead frame 10 of a very narrow pitch.

### First Manufacturing Method of Lead Frame of the Embodiment of the Invention

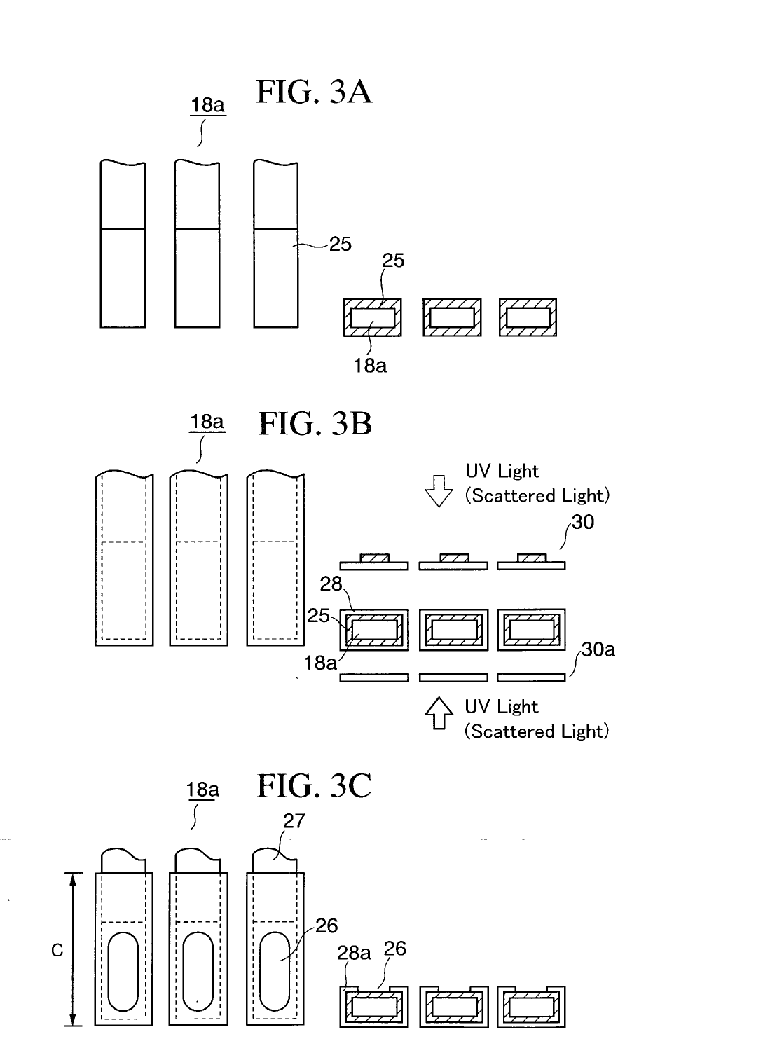

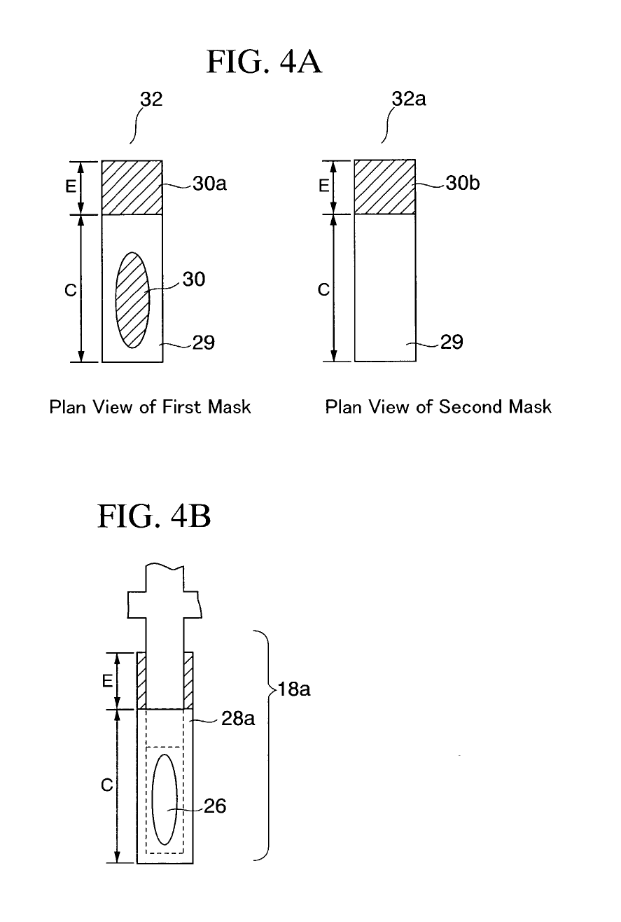

FIGS. 3A to 3C are partial plan and sectional views showing a first manufacturing method of the lead frame of the embodiment of the present invention, FIG. 4A is a partial plan view showing an example of an exposure mask in the first manufacturing method, and FIG. 4B is a partial plan view showing an example of an inner lead of the lead frame manufacture by the first manufacturing method.

### First Step: Preparation of Lead Frame

First, a lead frame having a predetermined area patterned is prepared by etching or stamping an Fe—Ni alloy sheet, a Cu alloy sheet or the like. Explanation is made by taking an example, where a pitch of tips of inner leads 18a is about 200 μm or less, a width thereof about 60 to 80 μm, and a space therebetween about 60 to 40 μm.

Then, as shown in FIG. 3A, a metal plating layer 25 such as gold (Au) plating layer, silver (Ag) plating layer or the like is formed in a predetermined area including the tip of the inner leads 18a.

### Second Step: Adhering and Cleaning of Lead Frame

Subsequently, in order to enhance adhesion with a cured resist film formed in a later step, at least an area including the inner lead 18a is surface-roughened properly. This surface-roughening may be carried out by weak blast treatment using aluminum beads or the like. Especially, in the case of using a substrate made of a hard material such as an Fe—Ni 42 alloy sheet or the like as a lead frame substrate, preferably, blast treatment and bab polishing are used in combination.

Then, the area including the inner lead 18a of the lead frame is subjected to chemical cleaning using chemical solution. For example, in the case of using a Cu alloy sheet for the lead frame substrate, chemical cleaning is persulfate or sulfur-hydrogen peroxide. Further, irradiation with an ultra violet (UV) light may be carried out as additional treatment.

### Third Step: Coating of Resist Coat Solution

Subsequently, as shown in FIG. 3B, negative type UV cured resist coat solution is coated on the metal plating layer 25. This resist coat solution can use one containing a modified epoxy (glycidyl ether type) resin, an acrylic resin or the like. As a coating method, a splaying method or a dipping method may be used, in which viscosity of the resist coat solution is several hundred poise or less. By this coating method, a resist coated film 28 having a thickness of, for example, about 5 to 10 μm can be formed on the inner lead 18a, i.e., on a full surface including both surfaces and side faces of the inner lead 18a.

Preferably, coating of the resist coated film 28 is prevented on the outer lead portion. In the case of using the spraying method, a pressing jig or the like is disposed on the outer lead portion beforehand to mask it. In the case of using the dipping method, the outer lead portion is masked by a tape or the like beforehand, and coating is carried out. Coating may be applied on an entire area of the inner lead 18a, or partially on a predetermined area thereof. The resist coated film 28 may be also formed on the entire lead frame without using

### Fourth Step: Drying of Resist Film

Subsequently, the resist coated film 28 formed on the inner lead 18a is dried in atmosphere of 70 to 80° for a predetermined time.

### Fifth Step: Exposure

Subsequently, similarly as shown in FIG. 3B, the resist coated film 28 is subjected to exposure in order to form an opening on the area of the resist coated film 28 corresponding to the inner lead 18a electrically connected to each of the semiconductor chip.

First, explanation is made for an exposure mask. As the resist coated film 28 of a negative type is used in the present embodiment, an exposed area is left as a pattern without being dissolved in developer because of bridging reaction. On the other hand, an unexposed area is dissolved in the developer and removed. That is, as shown in FIG. 4A, a first exposure mask 32 is prepared, which includes a light shielding film 30 formed in an area on a transparent glass substrate 29, equivalent to the area of the resist coated film 28 having the opening formed. As the resist coated film 28 must be left on a full rear surface of the inner lead 18a, a second exposure mask 32a having no light shielding layers formed on the transparent glass substrate 29 is prepared. According to the embodiment, a pattern of the resist coated film 28 is formed in an area C of the inner lead 18a. Thus, as show in FIG. 4A, light shielding films 30a and 30b are further formed respectively on the first and second exposure masks 32 and 32a to remove the resist coated film 28 of an area other than the area C.

Therefore, in the embodiment, the resist coated film 28 is coated in an area from the tip of the inner lead 18a to within an area E.

Then, as shown on a sectional view of FIG. 3B, the first exposure mask 32 is installed above the inner lead 18a, while the second exposure mask 32a is installed below the inner lead 18a. Exposure is carried out by using a normal metal halide mercury lamp (365 nm) as a light source and, for example, under a condition of 100 to 1000 mmJ/cm². At this time, in order to leave the resist coated film 28 on the side face of the area C of the inner lead 18a, a scattered light is used as a light source. By this scattered light, the resist coated film 28 on the side face of the area C of the inner lead 18a is also subjected to exposure. In the case of forming a resist film 28 on the entire lead frame, a predetermined exposure mask having a pattern of a light shielding film 30 similar to that of each of the first and second exposure masks 32 and 32a, and corresponding to the entire lead frame may be prepared, and a coated film 28 is similarly exposed by this as a mask.

### Sixth Step: Development

Subsequently, the exposed resist coated film 28 is developed in water-soluble alkali developer, e.g., 1% Na₂CO₃. In this time, the exposed area of the resist coated film 28 is left as a pattern without being dissolved in the developer because of bridging reaction, and the unexposed area is dissolved in the developer and removed, thus forming an opening 26 similar to that shown in FIG. 3C. As described above, this opening 26 has, for example, a width of about 60 μm, and a length of about 500 μm. In addition, in the embodiment, the pattern of the resist coated film 28 is formed only in the area C, and the resist coated film coated in the area E other than the area C is removed without being exposed. Accordingly, a inner lead 18a of an area 27 is exposed. Needless to say, dimensions of the opening 26 and the area C or the like can be optionally set by properly changing disposition of the light shielding films of the first and second exposure masks 32 and 32a.

Note that, in designing, as shown in FIG. 4A, the light shielding films 30a and 30b are formed in the area E of the first and second exposure masks 32 and 32a. Thus, the pattern of the resist coated film 28 is formed only up to the position of the area C of the inner lead 18a. However, as shown in FIG. 4B, the use of the scattered light facilitates illumination of the resist coated film 28 on the side face of the area E of the inner lead 18a. Consequently, the resist coated film 28 may be left on the side face (shaded portion of FIG. 4B) of the area E. Even in such a case, since the inner lead 18a portion is buried in a molded resin later, problems such as particle generation caused by peeling-off of the resist film on the side face never occur. That is, presence of an area having a resist coated film 28 formed only on a side face as shown in FIG. 4B causes no problems.

### Sixth Step: Postbaking

Subsequently, the resist coated film 28 is completely cured by subjecting the lead frame having the developed resist coated film 28 to post-baking under 15° C. to 170° C., and thus a cured resist film 28a is formed.

By the above steps, the lead frame of the embodiment manufactured by the first manufacturing method is completed.

### Modification of First Manufacturing Method of Lead Frame of the Embodiment

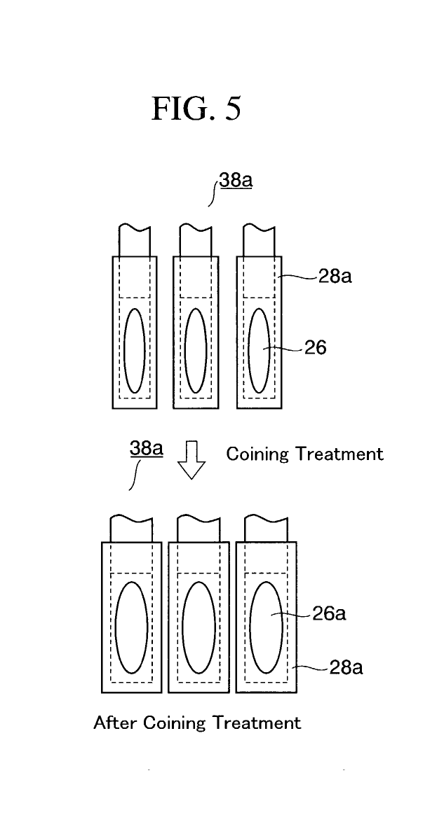

FIG. 5 is a partial plan view showing a modification of the first manufacturing method of the lead frame of the embodiment. In the modification of the first manufacturing method, a width of an inner lead is narrowed beforehand, and a width of an opening is widened to increase the width of the inner lead by executing coining treatment to the inner lead.

The coining treatment means compression processing carried out to obtain a predetermined surface shape. Especially, when a lead frame is manufactured by being stamped, so-called “burr” or “shear droop” easily occurs a processed edge, in the result, the case that a bonding area of the inner lead becomes small is presumed. In order to smooth the edge, the area including the tip of the inner lead or the like is extended by performing compression processing, thereby “burr” or “shear droop” of the inner lead is removed. Accordingly, a bonding area requested in designing can be secured.

First, as shown in FIG. 5 (upper figure), a lead frame having an inner lead 38a narrower than the width of the inner lead of the lead frame prepared in the first manufacturing method is prepared. Explanation is made by taking an example, where a width of the inner lead 38a is about 60 μm. and a space therebetween is about 40 μm.

Then, by a method similar to the first manufacturing method, the inner lead 38a is covered with a cured resist film 28a having an opening 26. In this case, the opening 26 is formed so as to have a width of about 45 μm. Then, a tip of the inner lead 38a including the opening 26 is compressed to be extended by a normal coining method. Thus, as shown in FIG. 5 (lower figure), the inner lead 38a having the width of 60 μm is increased to about, for example 66 μm, and the opening 26 is associatively extended. Thus, the opening 26 (FIG. 5 (upper figure)) having the width of about 45 μm is enlarged, thereby an opening 26a (FIG. 5 (lower figure)) having the width of about 50 μm is formed.

That is, even when a pitch of the inner leads 38a is narrowed, the relatively large opening 26a can be obtained by coining treatment. In this case, a space is narrowed between the inner leads 38a. However, because of covering the inner lead 38a with a cured resist film 28a, there is no possibility of electric short-circuiting even if the inner leads 38a are brought into contact with each other.

Thus, according to the modification of the first manufacturing method, even in the lead frame of a narrow pitch and many terminals, it is possible to obtain an opening of a sufficient area. Therefore, even in the case of a semiconductor device with a semiconductor chip highly densely mounted on the lead frame of a narrow pitch, it is possible to enhance reliability of electric connection with the semiconductor chip through a wire, and increase its manufacturing yield.

Note that, before the step of coating the organic insulating film on the inner lead 38a, the inner lead 38a may be subjected to coining treatment beforehand, then the organic insulating film may be coated on the inner lead 38a, and an enlarged opening 26a may be formed into the organic insulating film according to a width of the inner lead 38a extended by the coining treatment.

As described above, according to the first manufacturing method of the lead frame of the embodiment and its modification, even in the case of a lead frame having a narrow pitch, e.g., 120 μm or less, which is can be mounted with high reliability, and the necessity of a costly mounting using a high-level technology can be eliminated. Thus, costs can be greatly reduced.

### Second Manufacturing Method of Lead Frame of the Embodiment

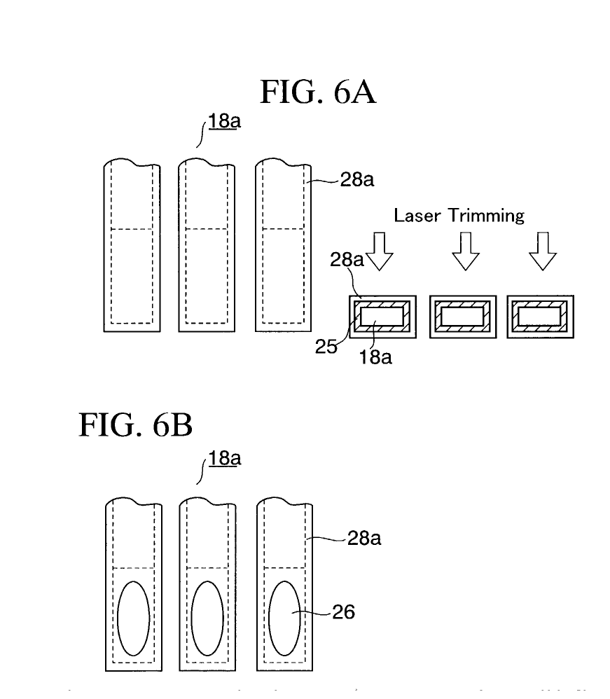

FIGS. 6A and 6B are partial plan and sectional views showing a second manufacturing method of the lead frame of the embodiment of the present invention.

First, as shown in FIG. 6A, by a method similar to the foregoing first manufacturing method, resist coat solution is coated on a predetermined area of an inner lead 18a, and the inner lead 18a is covered with a cured resist film 28a by executing postbaking in atmosphere of 170 to 180° C. In the second manufacturing method, an opening 26 is formed on the cured resist film 28a by laser trimming. Thus, a photosensitive resist is not always necessary and, preferably, a silicone-containing thermosetting resin or a thermoplastic resin as an elastic body is used.

Then, as shown on a sectional view of FIG. 6A, an area of the cured resist film 28a having the opening formed is irradiated with beam from a laser to thermally decompose the cured resist film 28a, thereby the opening 26 is formed.

As the laser, for example, a pulse YAG laser suited to micro-fabrication, or a carbon dioxide laser may be used. formed into the cured resist film 28a, and a part of the inner lead 18a is exposed in a bottom portion of the opening 26.

Subsequently, laser trimming is executed, and carbons in the cured resist film 28 are scattered in or in the vicinity of the opening 26. Thus, cleaning is carried out in aqueous solution containing manganese or chromium to remove the carbons.

By the above steps, the lead frame 10 of the embodiment manufactured by the second manufacturing method is completed.

The second manufacturing method of the lead frame of the embodiment has advantages similar to the first manufacturing method. Besides, since the opening 26 is formed into the cured resist film 28a by the laser trimming, the steps of exposure and development are omitted, thereby, the manufacture method can be simplified.

Note that, a read frame may be manufactured by combination with the second manufacturing method and the coining treatment described above in the modification. In this case, in the second manufacturing method, since the silicone-containing thermosetting cured resin which is the elastic body resin as the cured resist film 28a is used, a following characteristic to extension by compression of the alloy substrate in the inner lead 18a becomes good. In this matter, extension of the opening 26 is facilitated, and the area of the opening 26 can be enlarged easily.

The present invention has been described in detail by the embodiment. The scope of the present invention is not limited to the examples specified in the embodiment, and changes of the embodiment without departing from the invention are also within the scope of the invention.

For example, in the first manufacturing method, the resist film of the negative type was used as the cured resist film. Needless to say, however, a lead frame can be similarly manufactured by using a resist film of a positive type. In this case, a mask reversed black and white may be used as an exposure mask.

Furthermore, as the organic insulating film for covering the inner lead, the photosensitive resist film and the silicon-containing thermosetting resin are exemplified. Other than these, a photosensitive polyimide film or the like can be used, and any organic insulating films can be used as long as they can be subjected to patterning by photolithography or laser trimming.

What is claimed is:

1. A lead frame comprising:
an inner lead;
an outer lead connected to the inner lead; and
an insulating film covered on the inner lead, the insulating film having an opening formed on a predetermined area of the inner lead electrically connected to a semiconductor chip.

2. The lead frame according to claim 1, wherein the insulating film is an organic insulating film, and is a member selected from the group consisting of an epoxy thermosetting resin, an acrylic thermosetting resin, a silicon-containing thermosetting resin and a thermoplastic resin.

3. The lead frame according to claim 1, wherein an area of the inner lead including at least the opening of the insulating film is subjected to coining treatment after the formation of the opening.

4. The lead frame according to claim 1, wherein an arraying pitch of the inner lead is about 200 μm or less.

5. The lead frame according to claim 1, wherein a width of the opening in a direction perpendicular to a longitudinal direction of the inner lead is about 60 μm or more.

6. A method for manufacturing a lead frame, comprising the steps of:
preparing a lead frame including an inner lead having a metal plating layer;
covering an insulating film on the inner lead; and
forming an opening by patterning a required portion of the insulating film on the inner lead.

7. The method according to claim 6, wherein the insulating film is a photosensitive organic insulating film, and the step of forming the opening includes a step of exposing and developing the photosensitive organic insulating film.

8. The method according to claim 6, wherein the step of forming the opening is carried out by laser trimming.

9. The method according to claim 6, comprising additional step of carrying out coining treatment to a portion of the inner lead including at least the opening so as to increase the area of the opening after the step of forming the opening.

10. The method according to claim 8, wherein the insulating film is a silicone-containing thermosetting resin film.
